(19) United States
(12) Patent Application Publication
(10) Pub. No.: US 2026/0314473 A1
(43) Pub. Date: Oct. 8, 2026

(54) Semiconductor Device and Method of Making Using a Die and Pillar First Approach

(71) Applicant: STATS ChipPAC Pte. Ltd., Singapore (SG)

(72) Inventors: Yi Xiang Jasper Tay, Singapore (SG); Swain Hong Alfred Yeo, Singapore (SG); Chee Meng Law, Johor Bahru (MY); Junyi Zeng, Singapore (SG)

(73) Assignee: STATS ChipPAC Pte. Ltd., Singapore (SG)

(21) Appl. No.: 19/171,812

(22) Filed: Apr. 7, 2025

(51) Int. Cl. H01L 23/00; H01L 21/56; H01L 23/31; H01L 23/58

(52) U.S. Cl. CPC H10W 74/121; H10W 42/00; H10W 74/01; H10W 70/09; H10W 70/60

(57) ABSTRACT

A semiconductor device has a semiconductor die and a conductive pillar disposed adjacent to the semiconductor die. An encapsulant is deposited over the semiconductor die and conductive pillar. A first conductive layer is formed directly on the encapsulant, conductive pillar, and semiconductor die. A second conductive layer is formed directly on the encapsulant, conductive pillar, and semiconductor die opposite the first conductive layer.

### FIELD OF THE INVENTION

The present invention relates in general to semiconductor devices and, more particularly, to a semiconductor device and method of making using a die and pillar first approach.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Building up semiconductor packages on a carrier typically involves creating a reconstituted wafer with semiconductor die and pre-molded copper pillar modules, e-bars, or PCB units molded together into a panel. However, the prior art has problems with die shift resulting in bad units. The risk of die shift means that the line spacing and pitch cannot be as fine as technically possible based on the employed manufacturing method. A wider pitch must be used to ensure that the potential die shift is accommodated for. Accordingly, a need exists for a new die and pillar first approach.

### BRIEF DESCRIPTION OF THE DRAWINGS

FIGS. 1a-1c illustrate a semiconductor wafer with a plurality of semiconductor die separated by a saw street;

FIGS. 2a-2m illustrate forming a semiconductor package with a die and pillar first approach;

FIG. 3 illustrates an embodiment with through-silicon vias;

FIG. 4 illustrates an embodiment with pre-formed pillars;

FIGS. 5a-5h illustrate an embodiment with conductive blocks; and

FIGS. 6a and 6b illustrate an electronic device with the semiconductor packages.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function and description to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

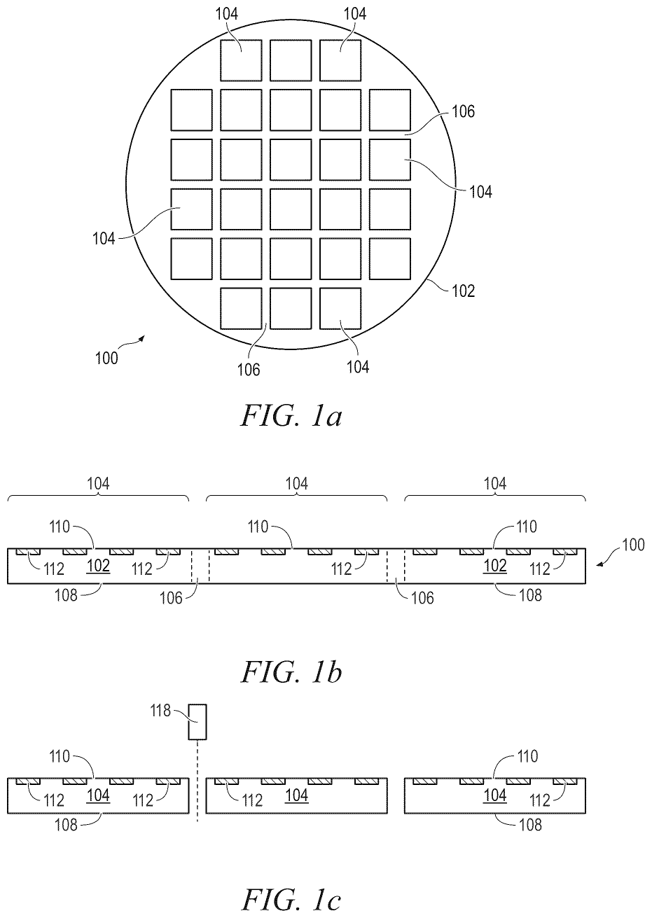

FIG. 1a shows a semiconductor wafer 100 with a base substrate material 102, such as silicon, germanium, aluminum phosphide, aluminum arsenide, gallium arsenide, gallium nitride, indium phosphide, silicon carbide, silicon nitride, lithium niobate (LiNbO3), or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed over or within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, power devices, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110. Semiconductor wafer 100 will typically have several interleaved insulating layers and conductive layers to implement the desired circuit design and signal routing, with conductive layer 112 being the top conductive layer. Any other conductive layer mentioned above or below can be formed using the same materials and methods as described for conductive layer 112.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die (KGD) or known good unit (KGU) after singulation.

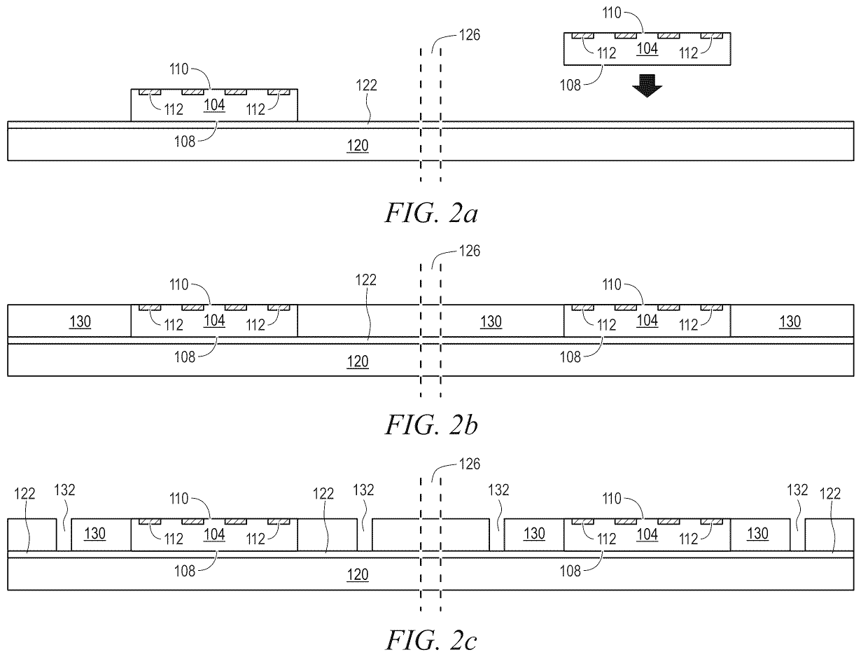

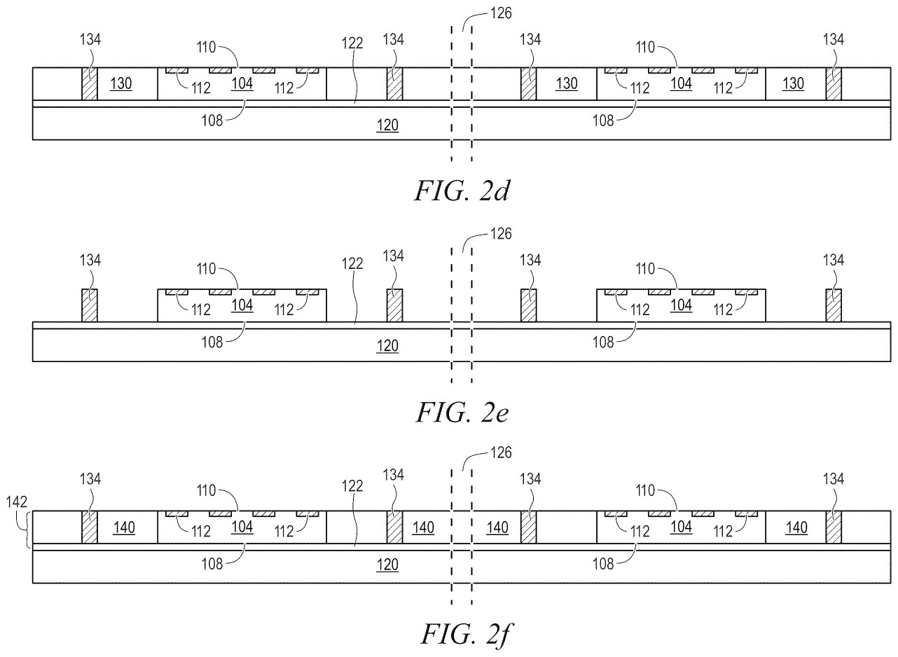

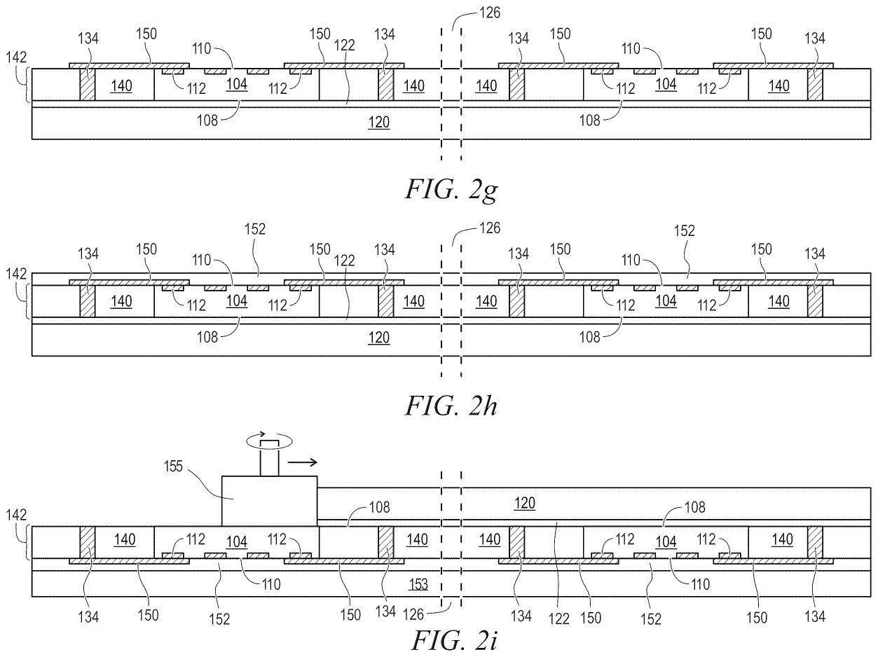

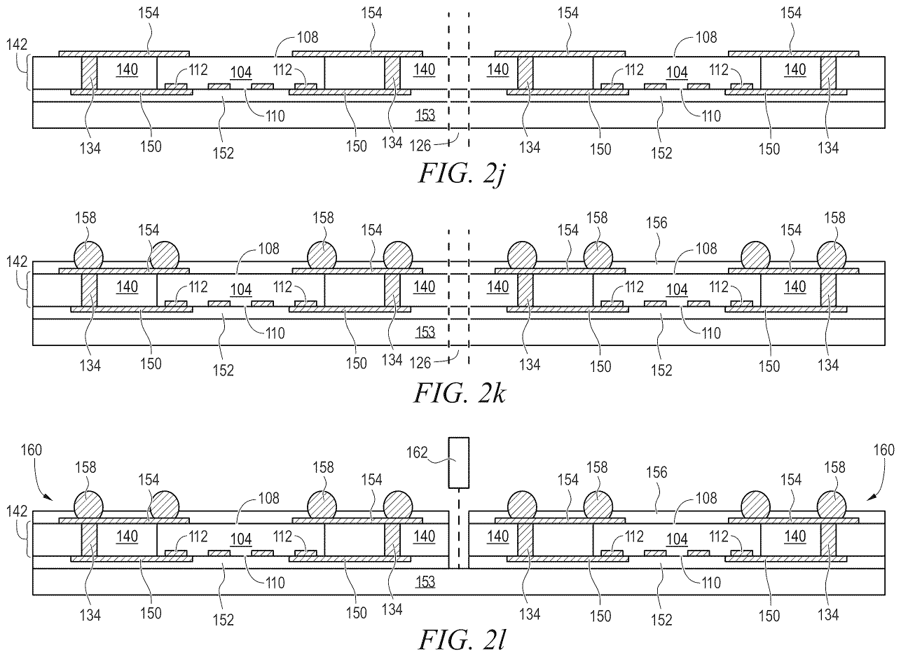

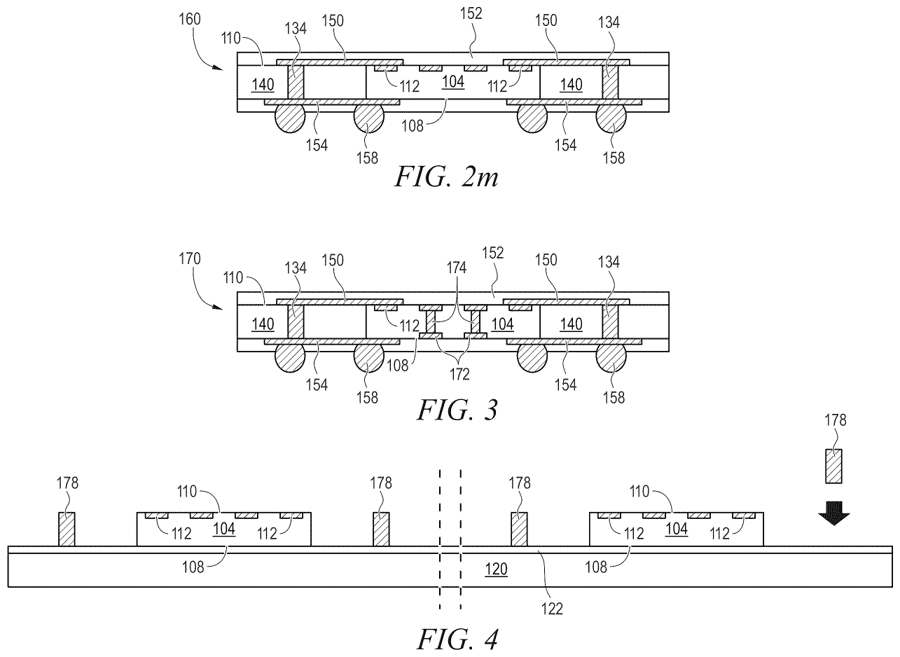

FIGS. 2a-2m illustrate a die and pillar first process of forming semiconductor packages with semiconductor die 104. FIG. 2a shows a carrier 120 with an optional interface layer, debonding adhesive layer, or double-sided tape 122 formed or disposed over carrier 120 as a temporary adhesive bonding film, etch-stop layer, thermal release layer, or UV release layer. Carrier 120 contains sacrificial base material such as silicon, polymer, beryllium oxide, glass, or other suitable low-cost, rigid material for structural support. The term carrier can refer to just carrier 120 or the combination of carrier 120 and interface layer 122.

Semiconductor die 104 are picked and placed onto carrier 120 with back surfaces 108 on interface layer 122. Alternatively, semiconductor die 104 are mounted onto carrier 120 with an adhesive layer disposed on back surface 108 without interface layer 122. One semiconductor die 104 is disposed on carrier 120 per package being manufactured, separated by a saw street 126. While a carrier 120 sufficient to form two packages at once is shown, typically hundreds or thousands of packages are formed together on a common carrier using the same steps disclosed herein but performed en masse. Any other electrical components desired to be packaged along with semiconductor die 104 can also be disposed on carrier 120 at the present stage, e.g., additional semiconductor die, sub-packages, chiplets, or discrete active or passive electrical components.

In FIG. 2b, photoresist layer 130 is formed on carrier 120, encapsulating semiconductor die 104 while leaving active surface 110 exposed and coplanar with the top surface of photoresist layer 130. Photoresist layer 130 may be formed using spin coating, spray coating, lamination, film-assisted molding or any other suitable method. Materials for photoresist layer 130 include photosensitive polyimide (PSPI), epoxy-based photoresists, acrylic-based photoresists, or any other suitable material. The thickness of photoresist layer 130 may vary depending on the desired conductive pillar dimensions and subsequent process requirements.

FIG. 2c shows via openings 132 formed completely through photoresist layer 130, exposing carrier 120 or interface layer 122. Photolithography is used to form via openings 132 by applying a patterned mask to photoresist layer 130, exposing selected areas to light, and developing the exposed or unexposed regions to form the openings. In other embodiments, via openings 132 are formed using laser ablation, plasma etching, or any other suitable method. The dimensions and placement of via openings 132 are tailored based on the specific application and desired electrical performance.

In FIG. 2d, conductive pillars 134 are formed by filling openings 132 with conductive material. Conductive pillars 134 can be formed of any of the materials described above for conductive layer 112 and deposited using any of the above-mentioned methods. Conductive material is typically deposited to overfill openings 132 and covering the top surface of photoresist layer 130 before being backgrinded or planarized to make conductive pillars 134 have top surfaces coplanar to photoresist layer 130 and semiconductor die 104. In other embodiments, conductive material is deposited using a bottom-up technique that is stopped when the conductive material completely fills openings 132 so that conductive pillars 134 are formed without a separate backgrinding step.

FIG. 2e illustrates photoresist layer 130 removed, leaving behind conductive pillars 134 and semiconductor die 104 on carrier 120. Photoresist layer 130 can be removed by wet stripping, plasma ashing, thermal decomposition, or any other suitable method. Upon removal, conductive pillars 134 remain on carrier 120 with top surfaces coplanar to active surface 110 of semiconductor die 104.

In FIG. 2f, an encapsulant or molding compound 140 is deposited over and around semiconductor die 104 and conductive pillar 134 using a paste printing, compression molding, transfer molding, liquid encapsulant molding, vacuum lamination, spin coating, or other suitable applicator to form a reconstituted wafer 142. Encapsulant 140 can be liquid or granular polymer composite material, such as epoxy resin, epoxy acrylate, or another suitable polymer, with or without a filler. Encapsulant 140 is non-conductive, provides structural support, and environmentally protects the semiconductor device from external elements and contaminants.

Encapsulant 140 is deposited with a top surface coplanar to top surfaces of conductive pillars 134 and semiconductor die 104 by using film-assisted molding or another method that leaves the encapsulated components exposed. In other embodiments, encapsulant 140 is deposited to completely cover conductive pillars 134 and semiconductor die 104 and is then backgrinded to expose the encapsulated components.

Reconstituted wafer 142 is so-called because semiconductor die 104 are repositioned and reassembled from wafer 100 into a new structure. The term reconstituted reflects that the original wafer 100 has been disaggregated and then reorganized into a new wafer. After encapsulation and planarization, the surface of reconstituted wafer 142 resembles that of a standard semiconductor wafer. This allows for further processing, such as redistribution layer (RDL) formation, similar to conventional wafer-level processes. Reconstituted wafer 142 functions like a traditional wafer but consists of multiple individual dies that have been encapsulated.

In FIG. 2g, a conductive layer 150 is formed on the coplanar surfaces of semiconductor die 104, encapsulant 140, and conductive pillars 134. Conductive layer 150 is a redistribution layer (RDL) with conductive traces that interconnect or fan-out contact pads of conductive layer 112 to conductive pillars 134. Each of the traces may have contact pads at each end, one over a contact pad of conductive layer 112 and one over a conductive pillar 134, to ensure electrical connection given the relevant manufacturing tolerances. Conductive layer 150 is formed directly on semiconductor die 104, which will typically have an insulating layer exposed between the contact pads of conductive layer 112 to prevent electrical short circuit with underlying conductive paths of the semiconductor die. Conductive layer 150 is also formed directly on conductive pillars 134 and encapsulant 140. Encapsulant 140, conductive pillars 134, and semiconductor die 104 have surfaces coplanar to each other so that conductive layer 150 is formed flat across all three.

Insulating layer 152 is formed over reconstituted wafer 142 with conductive layer 150 in FIG. 2h. Insulating layer 152 contains one or more layers of silicon dioxide (SiO2), silicon nitride (Si3N4), silicon oxynitride (SiON), tantalum pentoxide (Ta2O5), aluminum oxide (Al2O3), solder resist, polyimide (PI), photosensitive polyimide (PSPI), benzocyclobutene (BCB), polybenzoxazoles (PBO), and other material having similar insulating and structural properties. Insulating layer 152 can be formed using PVD, CVD, printing, lamination, spin coating, spray coating, sintering, or thermal oxidation. Any insulating, passivation, or dielectric layer mentioned above or below can be formed using any of the materials or methods described for insulating layer 152.

In other embodiments, insulating layer 152 is an encapsulant formed in a molding process. In those embodiments, insulating layer 152 can be formed of any of the materials and using any of the processes described above for encapsulant 140. In one embodiment, encapsulant 140 and insulating layer 152 are both formed using the same material and the same molding method, selected from any of those mentioned. A first molding process is used to deposit encapsulant 140 around semiconductor die 104 and conductive pillars 134 while a second molding process is used to form insulating layer 152. Insulating layer 152 completely covers reconstituted wafer 142 and conductive layer 150, electrically isolating the conductive layer and physically protecting both.

In FIG. 2i, reconstituted wafer 142 is flipped so that back surfaces 108 of semiconductor die 104 are oriented upward. Reconstituted wafer 142 is mounted onto backgrinding tape 153 or another suitable carrier and carrier 120 is removed by backgrinding with a grinder 155. Other processes suitable for removing the specific type of carrier 120 and interface layer 122 are used in other embodiments, e.g., UV or thermal release. As an alternative to backgrinding tape 153, another carrier can be attached over insulating layer 152 before flipping reconstituted wafer 142 and removing carrier 120.

In FIG. 2j, a conductive layer 154 is formed over the back surfaces of semiconductor die 104, encapsulant 140, and conductive pillars 134 opposite conductive layer 150. Conductive layer 154 is another RDL layer fanning in or out electrical connections from conductive pillars 134. Like conductive layer 150, conductive layer 154 is formed directly on coplanar surfaces of semiconductor die 104, encapsulant 140, and conductive pillars 134 to remain totally flat.

In FIG. 2k, insulating layer 156 is formed over reconstituted wafer 142 and conductive layer 154 as described above for insulating layer 152. As above, insulating layer 156 can be formed using the same type of molding process and same materials as both encapsulant 140 and insulating layer 152 in a third molding step. Insulating layer 156 is deposited to completely cover reconstituted wafer 142 and conductive layer 154.

Openings are formed through insulating layer 156 to expose contact pads of conductive layer 154 for external interconnect. The openings can be formed by laser ablation, mechanical drilling, chemical etching, or another suitable process. Solder bumps 158 are formed on conductive layer 154 in the openings of insulating layer 156. An electrically conductive bump material is deposited over conductive layer 154 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder.

The bump material is bonded to conductive layer 154 using a suitable attachment or bonding process. The bump material is optionally reflowed by heating the material above its melting point to form bumps 158. In one embodiment, bump 158 is formed over an under-bump metallization (UBM) having a wetting layer, barrier layer, and adhesion layer. The UBM can be formed over insulating layer 156 and conductive layer 154 after forming the openings in the insulating layer. Bump 158 can also be compression bonded or thermocompression bonded to conductive layer 154. In some embodiments, bumps 158 are formed before insulating layer 156. Solder bumps are electrically connected to conductive layer 112 of semiconductor die 104 through conductive layer 154, conductive pillars 134, and conductive layer 150.

Reconstituted wafer 142 is singulated into individual semiconductor packages 160 in FIG. 2l using a laser cutting tool 162 or another suitable means. FIG. 2m shows a package 160 after singulation. The singulated packages 160 are removed from backgrinding tape 153 and placed into a tape-and-real, JEDEC tray, or other suitable storage medium.

Semiconductor package 160 is a small package with encapsulant 140 being the same thickness as an embedded semiconductor die 104, and only a single flat conductive layer 150 or 154 and a single insulating layer 152 or 156 formed over each top and bottom surface of the encapsulant and semiconductor die. Depositing encapsulant 140 over carrier 120 with only semiconductor die 104 and bare conductive pillars 134 formed or disposed on the carrier, without being previously and separately molded, improves the design to reduce die shift. Moreover, the process eliminates the need for temporary bonding and debonding (TBDB) during manufacturing, thus reducing cost and complexity. TBDB is eliminated by removing carrier 120 using backgrinding and limiting processing thereafter such that backgrinding tape 153 can sufficiently support reconstituted wafer 142 through the remainder of the manufacturing process.

FIG. 3 illustrate an alternative embodiment wherein semiconductor package 170 has a semiconductor die 104 with backside contact pads 172 and conductive vias 174 for vertical interconnect to conductive layer 112 on active surface 110. Semiconductor die 104 is manufactured as described above, and then conductive vias 174 and contact pads 172 are formed. Contact pads 172 can be formed as described above for conductive layer 112. Conductive vias 174 are formed by forming openings through semiconductor die 104 using mechanical drilling, chemical etching, deep-reactive ion etching (DRIE), or another suitable means and then depositing a conductive material into the openings.

With backside contact pads 172, conductive layer 150 can be reconfigured to fan-out interconnection from the backside contact pads to solder bumps 158, thus relieving some of the burden on conductive layer 154 and loosening routing design constraints. Some solder bumps 158 are electrically coupled to conductive layer 112 through conductive layer 154, conductive pillars 134, and conductive layer 150, while other solder bumps 158 are electrically coupled to conductive layer 112 through conductive layer 154, contact pads 172, and conductive vias 174. Backside contact pads 172 are used without a conductive via 174 or without being connected to conductive layer 112 in other embodiments.

FIG. 4 illustrates an alternative embodiment wherein conductive pillars 178 are pre-formed and picked and placed onto carrier 120 instead of forming conductive pillars 134 directly on the carrier. Pillars 178 are formed on a separate carrier using a photolithographic mask, or by any other suitable means, and then picked and placed onto carrier 120 or into an intermediate storage medium, e.g., a tape-and-reel. Manufacturing of a semiconductor package proceeds as disclosed above in FIGS. 2f-2m.

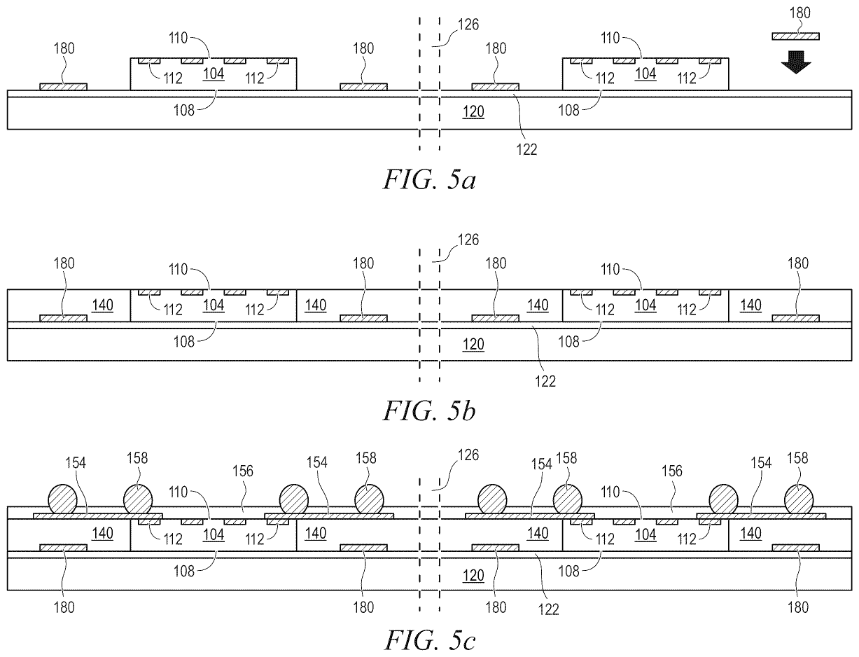

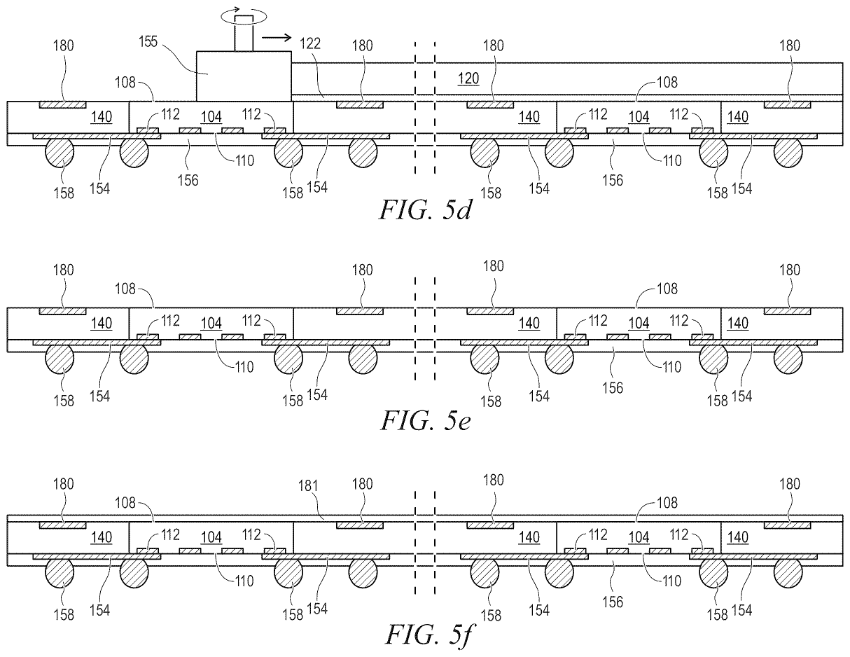

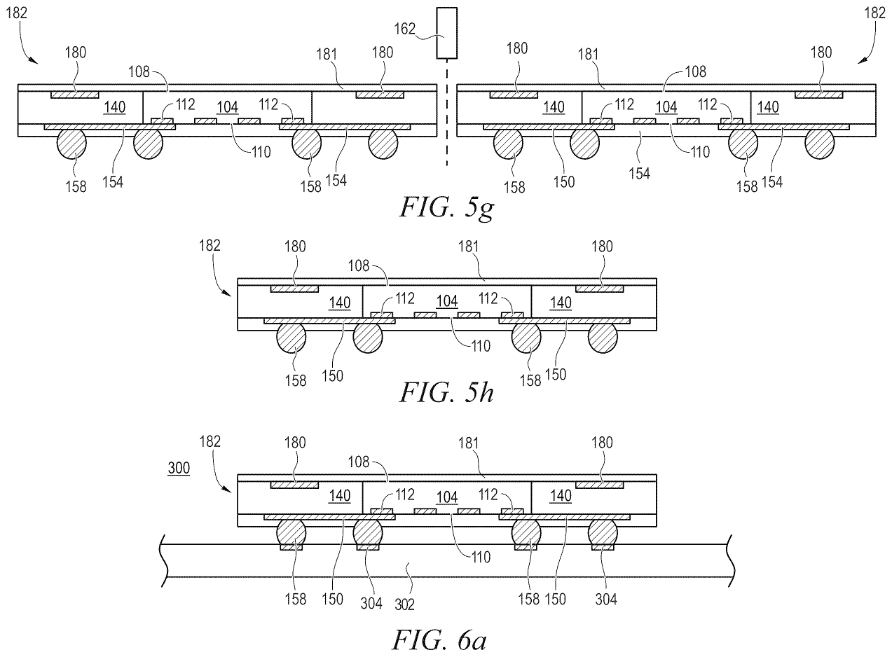

FIGS. 5a-5h illustrate a conductive block embodiment. Continuing from FIG. 2a, after semiconductor die 104 are disposed on carrier 120. FIG. 5a shows conductive blocks 180 being disposed onto carrier 120 around semiconductor die 104. Conductive blocks are formed using a photolithographic mask on a separate carrier, by cutting a sheet of conductive material to the desired size and shape, or by any other suitable means and then picked and placed onto carrier 120.

Alternatively, conductive blocks 180 can be formed directly on carrier 120 as shown and described above for conductive pillars 134 in FIGS. 2b-2e. Conductive blocks 180 can alternatively be formed on carrier 120 using any of the methods and materials described above for conductive layers generally. Conductive blocks 180 can be any desired size and shape, but are typically flat planar blocks suitable to shape, reflect, or amplify electromagnetic signals. Conductive blocks 180 are typically formed of copper, but any other suitable conductive material is used in other embodiments. Conductive blocks 180 are formed or disposed on carrier 120 prior to disposing semiconductor die 104 on the carrier in other embodiments.

FIG. 5b shows encapsulant 140 deposited and made coplanar to semiconductor die 104 as described above and shown in FIG. 2f, e.g., by using film-assisted molding. In FIG. 5c, conductive layer 154, insulating layer 156, and solder bumps 158 are formed as described above and shown in FIGS. 2j-2k. Conductive layer 154 extends over conductive block 180, which operates to shape or amplify radio signals being emitted by the conductive layer. Carrier 120 is removed by backgrinding or another suitable process in FIG. 5d to expose conductive blocks 180 and back surface 108 of semiconductor die 104. FIG. 5e shows the panel of devices with carrier 120 removed.

A backside protection layer 181 is formed over encapsulant 140, conductive blocks 180, and semiconductor die 104 in FIG. 5f. Backside protection layer 181 is formed using any of the methods and materials described above for insulating layers generally. In other embodiments, backside protection layer 181 is molded similarly to encapsulant 140. Backside protection layer 181 physically isolates and protects conductive blocks 180 and semiconductor die 104. A plurality of semiconductor packages 182 are singulated from each other in FIG. 5g using saw blade or laser cutting tool 162.

FIG. 5h shows a completed semiconductor package 182. Semiconductor package 182 is formed using a process that provides the same benefits from semiconductor package 160, e.g., no need for a TBDB process, a reduction in shifting issues allowing for a reduction in line spacing and pitch width, all while using existing established embedded wafer-level ball-grid array processes and tools. Semiconductor package 182 has conductive blocks 180 that help amplify or direct electromagnetic waves. In some embodiments, both conductive blocks 180 and conductive pillars 134 or 178 are used together by forming or disposing both on carrier 120 prior to depositing encapsulant 140.

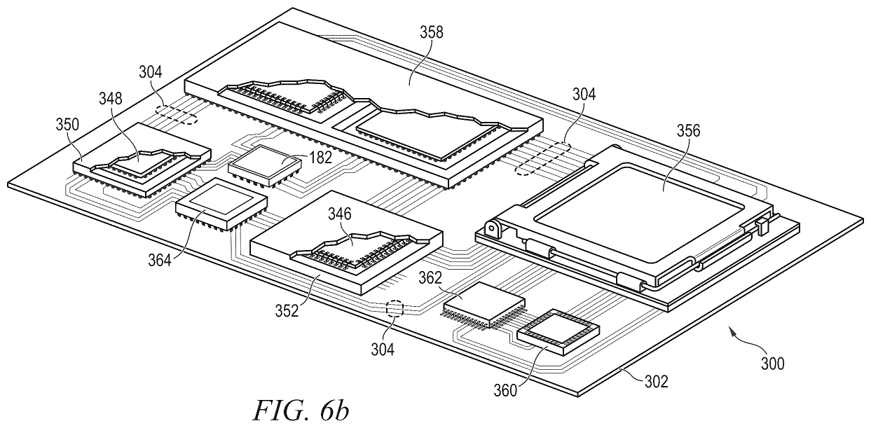

FIGS. 6a and 6b illustrate integrating the above-described semiconductor packages, e.g., semiconductor package 182, into a larger electronic device 300. FIG. 6a illustrates a partial cross-section of semiconductor package 182 mounted onto a printed circuit board (PCB) or other substrate 302 as part of electronic device 300. Solder bumps 158 are reflowed onto conductive layer 304 of PCB 302 to physically attach and electrically connect the semiconductor package to the PCB. In other embodiments, thermocompression or another suitable attachment and connection methods are used. In some embodiments, an adhesive or underfill layer is used between semiconductor package 182 and PCB 302. Semiconductor die 104 is electrically coupled to conductive layer 304 through bumps 158 and conductive layer 154, and, in some embodiments, conductive pillars 134 and conductive layer 150 as well.

FIG. 6b illustrates electronic device 300 having a chip carrier substrate or PCB 302 with a plurality of semiconductor packages disposed on a surface of PCB 302, including semiconductor package 182. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 6b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and are less expensive to manufacture, resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a semiconductor die;
disposing a conductive pillar adjacent to the semiconductor die;
depositing an encapsulant over the semiconductor die and conductive pillar;
forming a first conductive layer directly on the encapsulant, conductive pillar, and semiconductor die; and
forming a second conductive layer directly on the encapsulant, conductive pillar, and semiconductor die opposite the first conductive layer.

2. The method of claim 1, further including forming a conductive via through the semiconductor die.

3. The method of claim 1, further including:
molding the encapsulant in a first molding step; and
molding an insulating material over the first conductive layer in a second molding step.

4. The method of claim 3, further including disposing a solder bump on the second conductive layer.

5. The method of claim 4, further including forming an insulating layer over the second conductive layer around the solder bump.

6. The method of claim 1, further including:
disposing the semiconductor die and conductive pillar on a silicon carrier;
forming the first conductive layer while the semiconductor die and conductive pillar remain on the silicon carrier; and
removing the silicon carrier by backgrinding.

7. A method of making a semiconductor device, comprising:
providing a semiconductor die;
disposing a conductive element adjacent to the semiconductor die;
depositing an encapsulant over the semiconductor die and conductive element; and
forming a first conductive layer directly on the encapsulant and semiconductor die.

8. The method of claim 7, further including forming a conductive via through the semiconductor die.

9. The method of claim 7, further including:
molding the encapsulant in a first molding step; and
molding an insulating material over the encapsulant and semiconductor die opposite the first conductive layer in a second molding step.

10. The method of claim 9, further including disposing a solder bump on the first conductive layer.

11. The method of claim 10, further including forming an insulating layer over the first conductive layer around the solder bump.

12. The method of claim 7, further including:
disposing the semiconductor die and conductive element on a silicon carrier; and
removing the silicon carrier by backgrinding after depositing the encapsulant.

13. The method of claim 7, wherein the conductive element is a conductive block or conductive pillar.

14. A semiconductor device, comprising:
a semiconductor die;
a conductive pillar disposed adjacent to the semiconductor die;
an encapsulant deposited over the semiconductor die and conductive pillar;
a first conductive layer formed directly on the encapsulant, conductive pillar, and semiconductor die; and
a second conductive layer formed directly on the encapsulant, conductive pillar, and semiconductor die opposite the first conductive layer.

15. The semiconductor device of claim 14, further including a conductive via formed through the semiconductor die.

16. The semiconductor device of claim 14, further including an insulating material molded over the first conductive layer.

17. The semiconductor device of claim 16, further including a solder bump disposed on the second conductive layer.

18. The semiconductor device of claim 17, further including an insulating layer formed over the second conductive layer around the solder bump.

19. A semiconductor device, comprising:
a semiconductor die;
a conductive element disposed adjacent to the semiconductor die;
an encapsulant deposited over the semiconductor die and conductive element; and
a first conductive layer formed directly on the encapsulant and semiconductor die.

20. The semiconductor device of claim 19, further including a conductive via formed through the semiconductor die.

21. The semiconductor device of claim 19, further including an insulating material molded over the encapsulant and semiconductor die opposite the first conductive layer.

22. The semiconductor device of claim 21, further including a solder bump disposed on the first conductive layer.

23. The semiconductor device of claim 22, further including an insulating layer formed over the first conductive layer around the solder bump.

24. The semiconductor device of claim 19, wherein the conductive element is a conductive block or conductive pillar.

25. The semiconductor device of claim 19, wherein the semiconductor die and conductive element are disposed on a silicon carrier.
